(19) United States
(12) Patent Application Publication
(10) Pub. No.: US 2025/0210386 A1
(43) Pub. Date: Jun. 26, 2025

(54) Method and Apparatus for Calculating and Monitoring an Anomaly Score in Semiconductor Production

(71) Applicant: Robert Bosch GmbH, Stuttgart (DE)

(72) Inventors: David Walther Schoenleber, Karlsruhe (DE); Joseph Trotta, Adelfia (Bari) (IT); Keng Chai, Stuttgart (DE)

(21) Appl. No.: 18/981,483

(22) Filed: Dec. 14, 2024

(30) Foreign Application Priority Data
Dec. 22, 2023 (DE) 10 2023 213 320.2

(51) Int. Cl. H01L 21/67; G01R 31/28

(52) U.S. Cl. CPC H01L 21/67276; G01R 31/2831

(57) ABSTRACT

A computer-implemented method is disclosed for production quality testing in component manufacturing, in particular semiconductor manufacturing, based on a detection of a drift of data points in a data distribution over a reference data distribution, wherein the two data distributions each includes frequency distributions of anomaly values in an ensemble of components or reference elements, wherein a drift detection value is obtained as a weighted area under the curve, i.e. by the product of at least the determined cumulative distribution function of the reference data distribution and the data distribution integrated over the range from the smallest occurring anomaly value to the largest occurring anomaly value, and the drift detection value is compared to a predetermined drift threshold value. If the drift detection value exceeds the drift threshold value, the ensembles of components are flagged for further checking. The data distribution and/or reference data distribution are approximately determined as core density estimators based on the frequency distribution of the respective anomaly values using an FFT-based method.

This application claims priority under 35 U.S.C. § 119 to patent application no. DE 10 2023 213 320.2, filed on Dec. 22, 2023 in Germany, the disclosure of which is incorporated herein by reference in its entirety.

The disclosure relates to a method for production quality testing in component manufacturing, a computer program and a machine readable storage medium, as well as a device for processing data for production quality testing in component manufacturing.

### BACKGROUND

In multi-stage manufacturing processes, it may be particularly important for cost reasons to be able to identify and sort out defective components early on that have been manufactured in one process step and that are to be used in later stages of the manufacturing process. This is particularly true for the production of semiconductor chips. In the latter case, after a wafer level test (WLT) is carried out after production, during which all of the chips on the wafer are individually subjected to several tests indicative of the final performance of the chip. Chips that have passed the WLT test may then be assembled into a package along with chips of the same or different type as the end result of the at least two-step manufacturing process. The cost of disposing of chips in later process stages is higher than in earlier stages. This is why it is important to identify broken or abnormal chips early on in the WLT. Often, univariate measurements in the WLT are not able to identify all defective or abnormal chips. In DE102023200852.1, a method for determining an anomaly value for the chips in the context of the WLT is proposed. The anomaly value described may be determined from multivariate WLT sensor measurements and may provide an indication that an individual chip that has passed the previous WLT still has an anomaly.

The area under the receiver operating characteristic curve (AUC) is an aggregated measure of the quality of a binary classification model across all possible classification thresholds. In arXiv: 2107.02990 a weighted AUC is applied to a model for predicting deviations between two distributions.

A method for determining a core density estimator by way of the Fast Fourier Transform (FFT) is known from https://doi.org/10.2307/2347084.

### SUMMARY

According to one aspect of the present disclosure, a computer-implemented method for production quality testing in component manufacturing, in particular semiconductor manufacturing, is disclosed by identifying a drift of data points in a data distribution f_{obs}. The production quality test can in particular be the test on the wafer level, i.e. quality tests as part of wafer level tests (WLF). A drift may be a change or deviation of a data distribution from a reference distribution. For example, the reference distribution may have been determined at a particular point in time or may refer to measurements at a particular point in time. The data distribution may have been determined by associated measurements at a later time than the reference data distribution, or may refer to measurements at that later time. The data distribution f_{obs} is a frequency distribution of anomaly values. An anomaly value may be a value indicative of whether one or more sensor measurements on a component or a variable derived from the sensor measurements on the component is outside of predefined/specified limits. An anomaly value of a component may be a value that indicates or shows a probability that the component is abnormal, i.e., that it may have a defect. An anomaly value may also indicate whether or that a measured value is outside of a predetermined interval for this measurement. For example, the component cannot have shown any abnormalities in test measurements, e.g. univariate measurements, previously performed on the component. For example, an anomaly value may be determined by a machine learning system, wherein the machine learning system may receive multivariate sensor readings from test measurements of a component as input, and may output an anomaly value as output. It is also possible for anomaly values to be determined from one or more sensor measurements on a component by way of further analytical or numerical methods. For example, an anomaly value of a component may provide a measure of the extent to which, for example, derived and/or combined physical or chemical properties of the component deviate from a reference component. A reference component may be a component that meets the properties specified in a specification. The specification may be, for example, a document in which properties such as the electrical, chemical, mechanical, etc. properties of a non-defective component are precisely defined. The data distribution f_{obs} includes the frequency distribution of anomaly values in measurements on an ensemble of components. Furthermore, a reference data distribution f_{ref} is a frequency distribution of anomaly values from an ensemble of reference components. Preferably, a (reference) component may be a chip on a wafer, wherein the ensemble of (reference) components may preferably comprise all chips that are on a wafer. Alternatively, the ensemble of (reference) components may comprise the chips in a LOT. In one method step, the cumulative distribution function F_{ref} of the reference data distribution f_{ref} is determined. The cumulative distribution function F_{ref} can be determined from the reference data distribution by calculating the integral F_{ref}(x)=∫_{-∞}^{x}f_{ref}(x′) dx′. In a further step, a drift detection value is determined as the weighted area under the curve (AUC), wherein the weighted area under the curve is obtained by the product of at least the cumulative distribution function F_{ref} of the reference data distribution and the data distribution f_{obs} integrated over the range from the smallest occurring anomaly value to the largest occurring anomaly value. Then, in a next step, the determined drift detection value is compared to a predetermined drift threshold value. The ensemble of components will then be flagged for further checking if the drift detection value exceeds the drift threshold value. An flag may be added, for example, by tagging the ensemble of components with a tag, by marking a related ensemble number in a table, or by having a robot/user activate and sort out the ensemble. Additionally, or alternatively, the test gauge by which the sensor measurements have been taken on the ensemble of components from which the anomaly values have been determined may be labeled for further inspection. A method described above and in the following is characterized in that the data distribution f_{obs} and/or the reference data distribution f_{ref} is determined approximately as a core density estimator in each case, wherein the core density estimator of the data distribution and/or the core density estimator of the reference data distribution is determined based on the frequency distribution of the respective anomaly values using an FFT (Fast Fourier Transform) method.

Optionally, in a further step, an alert message can be output, for example, to a system for controlling a manufacturing test system and/or to a user of the manufacturing test system. The alert message may include a visual (light, display on control/computer screen) and/or audible alarm. Further, optionally in response to receiving an alert, a manufacturing test machine, such as a test gauge, may be stopped to further check this machine or test gauge, respectively.

Preferably, the individual components from the ensembles of components considered here have been classified as non-defective by previous measurements on the individual components as part of the quality inspections of the individual components.

For example, the weighted AUC determined in the method steps described herein may be interpreted as a measure for the overlap between the data distribution f_{obs} and the reference data distribution f_{ref}. The AUC may be determined by calculating the integral ∫_{-∞}^{∞}F_{ref}(x)f_{obs}(x)dx. To determine the weighted AUC, a threshold-dependent weighting function may be added to the product in the integral as a further factor. The weighted AUC may then be determined by ∫_{-∞}^{∞}F_{ref}(x)f_{obs}(x)dx, wherein denotes w(x) a threshold-dependent weighting function.

The AUC as well as the WAUC offer the advantage that drifts, i.e. displacements, of the data distribution f_{obs} or certain data points within the data distribution compared to the data distribution f_{ref} lead to lower anomaly values by the design of the AUC or WAUC to lower drift detection values. By design, the drift detection values are then still below the predetermined drift threshold value. Thus, with a method described herein, only those drifts—drifts in the data distribution f_{obs} towards higher anomaly values—are identified that may be associated with an anomaly of the ensemble of components or that may provide an indication of an anomaly of the ensemble.

The use of the FFT-based method for approximate determination of the data distribution and the reference data distribution in particular ensures a fast, efficient calculation of the weighted AUC. This may be particularly relevant in production quality testing during semiconductor manufacturing, in which a data distribution f_{obs} can be provided by an ensemble of HL components, for example by all chips on a wafer. In this application, a wafer can comprise thousands of chips and thus the data distribution can correspondingly comprise thousands of anomaly values. Alternatively, a data distribution f_{obs} may comprise the anomaly values of an ensemble of components, which may be provided by all of the chips in a LOT. A LOT can comprise hundreds of thousands of chips. A LOT can, for example, comprise 24 wafers. A method described above and below allows for a fast, resource-efficient and scalable calculation of the drift in the data distribution of anomaly values, particularly also in the case of (reference) data distributions comprising several thousand or several hundred thousand data points.

According to a preferred embodiment, the core density estimator of the data distribution and/or the core density estimator of the reference data distribution may be determined using the FFT-based method in which the following steps are performed. In a first step, a discrete approximation to the data distribution or the reference data distribution can first be determined by a histogram from the anomaly values of the data distribution or the reference data distribution on a grid of predetermined grid points. The associated FFT can be determined for each discrete approximation of the data distribution or reference data distribution, in each case in the form of a histogram. The predetermined grid points, by which the width of the bins of the respective histogram in particular can be determined, can each equal contested grid points. In a further step, the Fourier transform of the respective core density estimator may be determined by the product of the FFT of the respective discrete approximation to the data distribution or the reference data distribution and the Fourier transform of the core, respectively. Then, the core density estimator of the data distribution and/or the core density estimator of the reference data distribution may be determined by the inverse FFT of the determined Fourier transform.

The foregoing approach scales particularly well and allows components of an ensemble to be checked in a particularly time and resource-saving manner in semiconductor manufacturing. For example, data distributions of anomaly values, for instance, of an ensemble of components in the case of HL manufacturing can easily consist of hundreds of thousands to millions of data points.

Preferably, each core density estimator may have a Gaussian core. Alternatively, the core density estimator may have a different possible core.

According to a preferred embodiment, the cumulative distribution function F_{ref} can be determined in which the core density estimator approximating the reference data distribution f_{ref} is cumulatively integrated.

A quick numerical estimate of the cumulative distribution function F_{ref} may be obtained by a cumulative integration of the core density estimate f_{ref}.

Preferably, a one-dimensional, interpolating spline with constant extrapolation may be adjusted to the cumulative distribution function F_{ref}.

To efficiently and accurately calculate the weighted AUC, the cumulative distribution function F_{ref} should be known for any positive values, as the anomaly values in an observed data distribution f_{obs} may be much larger than the anomaly values in the reference data distribution which may be the basis for calculating the cumulative distribution function F_{ref}. To calculate the weighted AUC, F_{ref} should therefore be known on the support, for example the grid points, of the data distribution f_{obs}. Determining a one-dimensional interpolating spline with constant extrapolation to the cumulative distribution function F_{ref} ensures that F_{ref} is known on the support of the data distribution f_{obs} and so that the weighted AUC can be determined efficiently and accurately. If a Gaussian core is used to determine the reference data distribution f_{ref}, the cumulative distribution function to be determined is in particular smooth and a good approximation can be found by way of adjusting a spline.

According to a preferred embodiment, the core density estimator of the data distribution f_{obs} may be determined at a number of predetermined support locations. The one-dimensional interpolating spline, which may have been adjusted to the cumulative distribution function F_{ref}, may further be evaluated at the predetermined support locations of the data distribution. The weighted area under the curve can then be determined, in that the product of the interpolating spline evaluated at the predetermined support locations is formed with the core density estimator of the data distribution f_{obs} and with a weighting function, and this product is numerically integrated over the range from the smallest occurring anomaly value to the greatest occurring anomaly value in the predetermined support locations of the data distribution. Preferably, the weighting function has been determined or alternatively provided so that it can also be easily evaluated at the predetermined support locations of the data distribution.

Thus, the weighted area under the curve can be efficiently and precisely determined for data distributions f_{obs} and f_{ref} with a large number of data points, and a scalable solution for monitoring the drift in anomaly values is ensured.

According to a preferred embodiment, depending on the drift detection, i.e. if the drift detection value exceeds the drift threshold value, a flag will be set that characterizes that the anomaly detection model in particular, a machine learning system for determining an anomaly value of a component from sensor measurements on that component or another numerical or analytical method for determining an anomaly value of a component from sensor measurements on that component, is out of date, should be readjusted in particular depending on the measurements, or that the ensemble of components is abnormal, or that the test machine is defective. According to a preferred embodiment, an ensemble of components is provided by all the chips on a wafer or all the chips in a LOT. In this case, a flag set may indicate, among the other possibilities mentioned above, that the wafer comprising the ensemble of the measured components or which is the substrate for the ensemble of the measured chips may be abnormal.

Optionally, an alarm may be triggered in a further method step if the flag is set. The alarm may consist of displaying an alert on a screen for a user or operator in production quality testing, a visual and/or audible alarm, and/or an alarm signal transmitted to a controller of a testing device in quality testing. In the latter case, the transmitted alarm signal may cause the testing device that performed the quality control measurements on the wafer from which the corresponding anomaly values were determined to be stopped.

According to a preferred embodiment, an anomaly value may be determined from multivariate sensor measurements, wherein the multivariate measurements are wafer level test (WLT) measurements on semiconductor components, particularly on chips on a wafer.

WLT testing often takes into account only univariate deviations from a test specification. This may be improved, for example, by a machine learning system that takes into account the multivariate relationship of the values measured in the WLT and outputs an anomaly value for each chip in the WLT. A corresponding machine learning system may be trained on, for example, WLT data known to have produced a high proportion of good chips and may be used to predict an anomaly value for newly produced chips using the WLT measurements.

According to a preferred embodiment, the predetermined drift threshold value may have been determined using the steps described below. In one step, a plurality of N calibration distributions may have been received, wherein each calibration distribution may be a frequency distribution of anomaly values, in each case of an ensemble of reference components. Different calibration distributions can refer to different ensembles of reference components. For example, an ensemble of reference components may be provided by the chips of a wafer or the chips of a LOT. In a further step, a cumulative distribution function _{Fref,cal} may have been determined from the N calibration distributions. Furthermore, in a following step, a drift detection value for each of the N calibration distributions may be determined by calculating the weighted area under the curve with one of the N calibration distributions and the cumulative distribution function F_{ref,cal} respectively. The determined N drift detection values may deviate from one other and reflect the variability of the anomaly values between different wafers. In a following step, the drift threshold value may be determined from the distribution of the determined N drift detection values as a quantile of that distribution.

Advantageously, in the calibration described above, the natural structure of the ensembles of components is used, which is provided in that the chips belong to the same wafer. Specifically, by determining the drift threshold value according to the steps described above, an accepted false-positive rate for detecting anomalous data drift is specified. The above-described steps advantageously allow the drift threshold value to be set in a transparent manner and a manner adapted to the semiconductor domain. In particular, this method makes it simple to incorporate domain expert preferences and knowledge when establishing the quantile.

Preferably, the quantile of distribution of the determined N drift detection values indicating the drift threshold value may be given by one of the percentiles between the 90th percentile and the 100th percentile. For example, the drift threshold value may be given by one of the percentiles between the 94th percentile and the 100th percentile, e.g., by the 95th percentile or the 99th percentile.

The percentile may be advantageously chosen, in particular, by a domain expert based on their domain knowledge or preferences.

According to a preferred embodiment, when determining a drift detection value as a weighted area under the curve, a threshold-dependent weighting function may be added to the product of at least the cumulative distribution function F_{ref} of the reference data distribution and the data distribution f_{obs} as a further factor.

Adding a threshold-dependent weighting function when calculating the weighted area under the curve allows the impacts of threshold effects to be suppressed. For example, threshold effects could occur when artifacts in the data distribution f_{obs} are given too much weight in calculating the area under the curve, such as when these artifacts occur in the range of the increase in the cumulative distribution function F_{ref}. Such threshold effects may be advantageously suppressed by introducing a threshold-dependent weighting function. A threshold-dependent weighting function can also ensure that moderate changes to the data distribution f_{obs} do not have a significant impact on the WAUC statistics.

According to a preferred embodiment, the threshold-dependent weighting function may be obtained by adjusting a distribution to the cumulative distribution function and using this adjusted distribution as the basis for determining the threshold-dependent weighting function. Preferably, this distribution may be given by the distribution function of a log-normal distribution. Alternatively, it is possible to adjust other distributions instead of the distribution function of a log-normal distribution.

Often, the anomaly values may be approximated by a log-normal distribution. However, the reference distribution of anomaly values may have some artifacts, such as additional “imperfections” or artifacts at the edges, for instance longer tails. To make the WAUC more robust with respect to such artifacts, for instance to avoid reducing the detection sensitivity for displacements towards larger anomaly values due to artifacts in the reference distribution, a log-normal distribution may be adjusted to the cumulative distribution function of the reference distribution and this adjusted cumulative distribution function may be used in the weighting function w when calculating the WAUC. Advantageously, the sensitivity of the drift detection may be further increased by decreasing the exponent in the adjusted log-normal distribution that is used in the weighting function. Conversely, the sensitivity of drift detection may be reduced by increasing the exponent in the adjusted log-normal distribution.

Preferably, the threshold-dependent weighting function may be given by a potency of the adjusted distribution.

For example, the threshold-dependent weighting function w(x) may be given by F̅_{ref}ⁿ(x), wherein F̅_{ref}(x) the adjusted distribution is designated and n is a natural number to which potency the adjusted distribution is to be F̅_{ref}(x) taken. This approach can ensure that only drifts of the data distribution f_{obs} towards higher anomaly values contribute to the drift detection value.

Furthermore, the disclosure relates to a computer program with machine-readable instructions which, when executed on one or more computers, cause the computer(s) to perform the method described below and above. The disclosure also comprises a machine-readable data medium on which the above computer program is stored, as well as a computer or data processing device equipped with the aforementioned computer program and/or the aforementioned machine-readable data medium.

### BRIEF DESCRIPTION OF THE DRAWINGS

Embodiments of the disclosure are explained in greater detail below with reference to the accompanying drawings. In the drawings:

FIG. 1 schematically illustrates an information flow overview of a method described herein;

FIG. 2 schematically illustrates another information flow overview of a method described herein;

FIG. 3 shows a data processing device comprising means for performing a method described herein.

### DETAILED DESCRIPTION

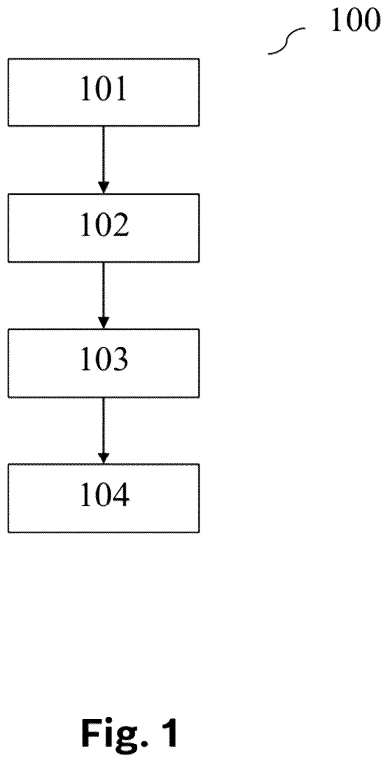

FIG. 1 schematically illustrates an information flow overview of a computer-implemented method 100 for production quality testing in component manufacturing based on detection of data point drift in a data distribution f_{obs}. This can, in particular, be production quality testing in semiconductor manufacturing. The data distribution f_{obs} may comprise a frequency distribution of anomaly values of an ensemble of components. A component may be, for example, a chip, and an ensemble of components may comprise all of the chips that are on a wafer or in a LOT. A reference data distribution f_{ref} may be given by a frequency distribution of anomaly values of an ensemble of reference components, for example a reference wafer or a reference LOT. The method 100 may comprise the steps described hereinafter. In step 101, the associated cumulative distribution function F_{ref} of the reference data distribution is determined from the reference data distribution f_{ref}. In step 102, a drift detection value is determined as a weighted area under the curve (WAUC). The weighted area under the curve can be obtained by the product of at least the cumulative distribution function F_{ref} of the reference data distribution and the data distribution f_{obs} integrated over the range from the smallest occurring anomaly value to the largest occurring anomaly value. In step 103, the drift detection value is compared to a predetermined drift threshold value. Then, the ensembles of components may be labeled for further checking in step 104 if the drift detection value exceeds the drift threshold value. Additionally, or alternatively, the test measurement device by which the measurements have been taken on the ensemble of components from which the anomaly values have been determined may be labeled for further inspection. The method 100 is in particular characterized in that the data distribution f_{obs} and/or the reference data distribution f_{ref} is approximately determined as a core density estimator. The core density estimator of the data distribution and/or the core density estimator of the reference data distribution is determined based on the frequency distribution of the respective anomaly values using an FFT-based method.

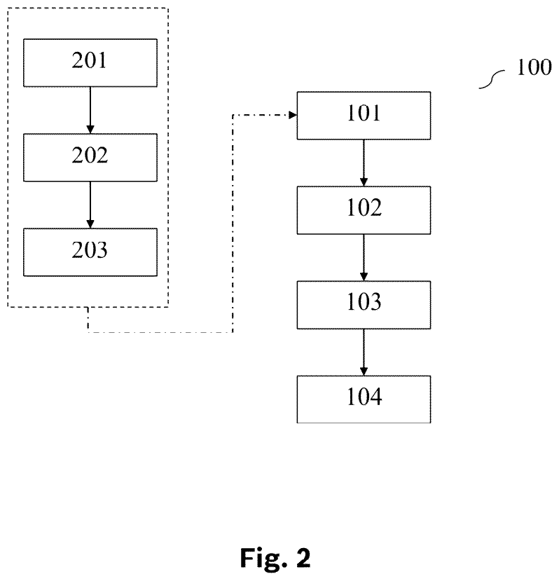

FIG. 2 schematically shows another information flow overview of a computer-implemented method 100 for production quality testing in component manufacturing. The method steps 101, 102, 103 and 104 have already been described in connection with FIG. 1. FIG. 2 shows further method steps 201, 202, and 203 relating to determining the core density estimators by way of an FFT-based method. These steps may preferably be performed before determining the cumulative distribution function in method step 101, since the reference distribution f_{ref} should be known to determine the latter. In step 201, a discrete approximation to the data distribution or the reference data distribution is determined by a histogram on a grid of predetermined grid points. For the respective discrete approximation, the FFT of this discrete approximation is determined in each case. In step 202, the Fourier transform of the respective core density estimator is determined by the product of the FFT of the respective discrete approximation and the Fourier transform of the core. For example, the core may be given by a Gaussian core. In step 203, the core density estimator of the data distribution and/or the core density estimator of the reference data distribution is determined by the inverse FFT of the determined Fourier transform.

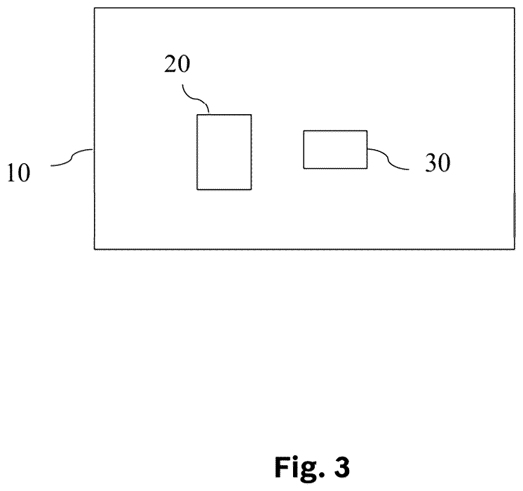

FIG. 3 shows an exemplary embodiment of a data processing device 10 comprising at least one processor 30 and at least one machine-readable storage medium 20, wherein the machine-readable storage medium 20 contains instructions that, when executed by the processor 30, cause the data processing device 10 to perform a method according to any of the aspects of the disclosure.

The term “computer” includes any device for processing specifiable calculation rules. These calculation rules can be provided in the form of software or in the form of hardware or also in a mixed form of software and hardware.

A plurality can be generally be understood as being indexed, i.e. each element of the plurality is allocated a unique index, preferably by allocating consecutive whole numbers to the elements included in the plurality. If a plurality N comprises elements, wherein N is the number of elements in the plurality, the elements are preferably allocated whole numbers from 1 to N.

What is claimed is:

1. A computer-implemented method for production quality testing in component manufacturing based on detection of a drift of data points in a data distribution, wherein the data distribution is a frequency distribution of anomaly values, wherein the data distribution comprises the frequency distribution of anomaly values in measurements on an ensemble of components, and wherein a reference data distribution is a frequency distribution of anomaly values from an ensemble of reference components, the method comprising:
determining the cumulative distribution function of the reference data distribution;
determining a drift detection value as a weighted area under the curve, wherein the weighted area under the curve is obtained by the product of at least the cumulative distribution function of the reference data distribution and the data distribution integrated over the range from the smallest occurring anomaly value to the largest occurring anomaly value;
comparing the drift detection value to a predetermined drift threshold value; and
labeling the ensemble of components for further verification when the drift detection value exceeds the drift threshold value,
wherein the data distribution and/or the reference data distribution is/will be approximately determined as a core density estimator, and
wherein the core density estimator of the data distribution and/or the core density estimator of the reference data distribution is determined based on the frequency distribution of the respective anomaly values by an FFT-based method.

2. The method of claim 1, wherein the core density estimator of the data distribution and/or the core density estimator of the reference data distribution is determined by the FFT-based method in which
a discrete approximation to the data distribution or the reference data distribution is determined by a histogram using a grid of predetermined grid points and the FFT of said discrete approximation is determined in each case,
the Fourier transform of the respective core density estimator is determined by the product from the FFT of the respective discrete approximation and the Fourier transform of the core, and
the core density estimator of the data distribution and/or the core density estimator of the reference data distribution is determined by the inverse FFT of the determined Fourier transform.

3. The method according to claim 1, wherein each core density estimator has a Gaussian core.

4. The method according to claim 1, wherein the cumulative distribution function is determined in which the core density estimator approximating the reference data distribution is cumulatively integrated.

5. The method according to claim 1, wherein a one-dimensional interpolating spline with constant extrapolation is adjusted to the cumulative distribution function.

6. The method according to claim 5, wherein:
the core density estimator of the data distribution is determined at a number of predetermined support locations,
the one-dimensional interpolating spline adapted to the cumulative distribution function is evaluated at the predetermined support locations of the data distribution, and
the weighted area under the curve is determined, in that the product of the interpolating spline evaluated at the predetermined support locations is formed with the core density estimator of the data distribution determined at the predetermined support locations and with a weighting function and numerically integrated over the range from the smallest occurring anomaly value to the largest occurring anomaly value in the predetermined support locations of the data distribution.

7. The method according to claim 1, wherein:
depending on the drift detection, a flag is set that characterizes that the anomaly detection model is out-of-date, particularly adjusted depending on the measurements, or that the wafer is abnormal, or that the test machine is defective.

8. A device for data processing, comprising means for carrying out the method according to claim 1.

9. A computer program comprising instructions which, when the program is executed by a computer, cause the computer to carry out the method according to claim 1.

10. A computer-readable storage medium comprising instructions which, when executed by a computer, cause the latter to carry out the method according to claim 1.

11. The method of claim 1, wherein the component manufacturing is semiconductor manufacturing.
